(19) United States
(12) Patent Application Publication
(10) Pub. No.: US 2023/0080701 A1
(43) Pub. Date: Mar. 16, 2023

(54) LIGHT EMITTING DEVICE AND OPTICAL MEASUREMENT APPARATUS

(71) Applicant: FUJIFILM BUSINESS INNOVATION CORP., Tokyo (JP)

(72) Inventors: Takashi KONDO, Kanagawa (JP); Michiaki MURATA, Kanagawa (JP); Seiji ONO, Kanagawa (JP)

(73) Assignee: FUJIFILM BUSINESS INNOVATION CORP., Tokyo (JP)

(21) Appl. No.: 17/712,547

(22) Filed: Apr. 4, 2022

(30) Foreign Application Priority Data
Sep. 14, 2021 (JP) 2021-149244
Sep. 14, 2021 (JP) 2021-149245

(51) Int. Cl. H01L 27/15; G01S 17/10; G09G 3/32; H01L 33/62; H01L 25/075

(52) U.S. Cl. CPC H01L 27/156; G01S 17/10; G09G 3/32; H01L 33/62; H01L 25/0753

(57) ABSTRACT

A light emitting device, includes: a semiconductor substrate; a light-emitting-element section formed on the semiconductor substrate and including plural light emitting elements that radiate light; a signal line that is formed on the semiconductor substrate and that transmits a signal to the light emitting elements; and an oxide film formed between the signal line and the semiconductor substrate along an extension direction of the signal line.

### CROSS-REFERENCE TO RELATED APPLICATIONS

This application is based on and claims priority under 35 USC 119 from Japanese Patent Application No. 2021-149244 filed Sep. 14, 2021 and. Japanese Patent. Application No. 2021-149245 filed Sep. 14, 2021.

### BACKGROUND

### (i) Technical Field

The present disclosure relates to a light emitting device and an optical measurement apparatus.

### (ii) RELATED ART

Japanese Unexamined Patent Application Publication No. 2009-286048 discloses a self-scanning light source head including a substrate, a surface-emitting semiconductor laser arranged in an array on the substrate, and a thyristor as a switching element arranged on the substrate to selectively turn on and off light emitted from the surface-emitting semiconductor laser, and also discloses an image forming apparatus using the light source head.

Japanese Unexamined Patent Application Publication No. 2001-308385 discloses a self-scanning light emitting element that constitutes a light emitting element having a pnpnpn six-layer semiconductor structure, in which electrodes are provided in a p-type first layer and an n-type sixth layer at both ends and in a p-type third layer and an n-type fourth layer at the center, a pn layer functions as a light emitting diode, and pnpn four layers function as a thyristor.

Japanese Unexamined Patent Application Publication No. 2018-006502 discloses a light emitting component including a substrate in which a second semiconductor stack is grown on a first semiconductor stack via a tunnel junction layer or a group III-V compound layer having metallic electric conductivity, plural light emitting elements constituted by the first semiconductor stack, and a driver including a thyristor by the second. semiconductor stack and configured to sequentially drive the plural light emitting elements to a state in which transition to an on state is possible.

Japanese Unexamined Patent Application Publication No. 2020-120018 discloses a light emitting device including a light emitter in which plural light-emitting-element groups each having plural light emitting elements are arranged, and the light emitter is configured such that the plural light emitting elements included in each of the plural light-emitting-element groups are sequentially set in a light emitting state or a non-light emitting state in parallel for each of the plural light-emitting-element groups along the arrangement.

### SUMMARY

In a so-called monolithic light emitting substrate in which a light emitting element and a signal line for transmitting a signal to the light emitting element are formed on the same substrate, when a leakage current from a light-emitting-element section is transmitted to the signal line, light emission efficiency is decreased. In addition, the signal line is erroneously lit.

Aspects of non-limiting embodiments of the present disclosure relate to providing a light emitting device and an optical measurement apparatus that prevent a decrease in light emission efficiency due to transmission of a leakage current to a signal line even when the leakage current from. a light-emitting-element section occurs.

Aspects of non-limiting embodiments of the present disclosure also relate to providing a light emitting device and an optical measurement apparatus that prevent erroneous lighting of a signal line due to transmission of a leakage current from a light-emitting-element section to the signal line.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device, including: a semiconductor substrate; a light-emitting-element section formed on the semiconductor substrate and including a plurality of light emitting elements that radiate light; a signal line that is formed on the semiconductor substrate and that. transmits a signal to the light emitting elements; and an oxide film formed between the signal line and the semiconductor substrate along an extension direction of the signal line.

### BRIEF DESCRIPTION OF THE DRAWINGS

Exemplary embodiments of the present disclosure will be described in detail based on the following figures, wherein:

FIG. 1 is an explanatory plan view illustrating a light emitting chip according to a first exemplary embodiment of the present disclosure;

FIG. 2 is an enlarged explanatory view illustrating the light emitting chip illustrated in FIG. 1;

FIG. 3 is a circuit diagram illustrating an equivalent circuit of the light emitting chip illustrated in FIG. 1;

FIG. 4 is a sectional view illustrating a sectional structure taken along line IV-IV indicated in FIG. 2;

FIG. 5 is a sectional view illustrating a sectional structure taken along line V-V indicated in FIG. 2;

FIG. 6 is an explanatory plan view illustrating a light emitting chip according to a second exemplary embodiment of the present disclosure;

FIG. 7 is an enlarged explanatory view illustrating the light emitting chip illustrated in FIG. 6;

FIG. 8 is a sectional view illustrating a sectional structure taken along line VIII-VIII indicated in FIG. 7;

FIG. 9 is a plan view of the light emitting chip in which a resistor is formed in the middle of a signal line;

FIG. 10 is an enlarged. view illustrating the resistor;

FIG. 11 is a sectional view illustrating a sectional structure taken along line XI-XI of FIG. 10;

FIG. 12 illustrates an outline of a smartphone in which the light emitting chip is used;

FIG. 13 illustrates a functional configuration example of the smartphone;

FIG. 14A and 14B illustrate a modification of the light emitting device;

FIG. 15 illustrates the modification of the light emitting device;

FIG. 16 is an explanatory plan view illustrating a light emitting chip according to a third exemplary embodiment of the present disclosure;

FIG. 17 is an enlarged sectional view illustrating a light emitting element;

FIG. 18 is an enlarged view illustrating a resistor;

FIG. 19 is a sectional view illustrating a sectional structure taken along line XIX-XIX of FIG. 18;

FIG. 20 illustrates an outline of a smartphone in which the light emitting chip according to the exemplary embodiment is used;

FIG. 21 illustrates a functional configuration example of the smartphone;

FIGS. 22A and 22B illustrate a modification of the light emitting device; and

FIG. 23 illustrates the modification of the light emitting device.

### DETAILED DESCRIPTION

Exemplary embodiments of the present disclosure will be described. below with reference to the drawings. In the drawings, the same or equivalent components and portions are denoted by the same reference numerals. The dimensional ratios in the drawings are exaggerated for convenience of explanation, and may be different from actual ratios.

Hereinafter, an exemplary mode in which a vertical cavity surface emitting laser (VCSEL) is applied as a light emitting element according to an exemplary embodiment of the present disclosure will be described; however, the present disclosure is not limited thereto, and an exemplary mode in which a light emitting diode (LED) or the like is applied may be employed.

### First Exemplary Embodiment

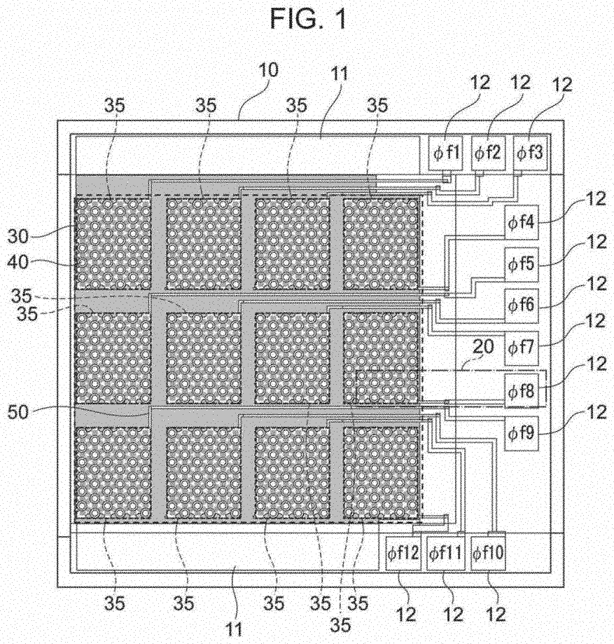

FIG. 1 is an. explanatory plan view illustrating a light emitting chip according to a first exemplary embodiment of the present disclosure. A light emitting chip 10 illustrated in FIG. 1 includes an anode electrode 11, a gate electrode 12, and a light-emitting-element section 30. The light-emitting-element section 30 includes plural light emitting elements 40.

The anode electrode 11 is an anode-side electrode formed in a portion of a wire extending from an anode electrode formed in the light-emitting-element section 30. The anode electrode 11 applies a predetermined voltage VLD to the light-emitting-element section 30. In the present exemplary embodiment, an exemplary mode in which anode electrodes 11 are provided at both ends of the light emitting chip 10 will be described; however, the present disclosure is not limited to the mode, and an appropriate number of anode electrodes 11 may be provided in consideration of mounting or the like of the light emitting chip 10.

The gate electrode 12 is an electrode that supplies a signal for causing each light emitting element 40 of the light-emitting-element section 30 to emit light. In the present exemplary embodiment, as will be described later, the light-emitting-element section 30 includes twelve areas 35 as illustrated in FIG. 1. Thus, the light emitting chip 1.0 illustrated in FIG. 1 includes twelve gate electrodes 12 to allow the light emitting elements 40 of each area 35 to independently emit light. The light emitting elements 40 emit light. with a current supplied to the anode electrodes 11, and hence power required for light emission is supplied to the anode electrodes 11. In contrast, signals for light emission are supplied to the gate electrodes 12, and hence the voltage that is supplied to the gate electrodes 12 is smaller than the voltage that is supplied to the anode electrodes 11. Specifically, the voltage that is supplied to the gate electrodes 12 may be about 5 V to 10 V. The arrangement pattern of the gate electrodes 12 is not limited to the example illustrated in FIG. 1. The number of areas 35 is not limited to twelve.

The light-emitting-element section 30 includes the plural light emitting elements 40. In the present exemplary embodiment, the light-emitting-element section 30 corresponds to a region that covers all the light emitting elements 40 formed on the light emitting chip 10. In the present exemplary embodiment, assuming that an up-down direction of FIG. 1 indicates a row, the light emitting elements 40 arranged in each row are arranged at a predetermined interval. In contrast, when viewed in a left-right direction of FIG. 1, the light emitting elements 40 are arranged at a predetermined interval in every other row. Adjacent rows are shifted in the up-down direction by half the size of each light emitting element 40, and hence the light emitting elements 40 are arranged in a so-called staggered form. However, the arrangement of the light emitting elements 40 is not limited to the staggered form, and for example, the light emitting elements 40 may be arranged in a so-called array form in which the light emitting elements 40 are arranged in each row at a predetermined interval and the positions of the light emitting elements 40 in adjacent rows are not shifted in the up-down direction. The number of light emitting elements 40 may be an appropriate number in consideration of output power or the like required for the light emitting chip 10. In the present exemplary embodiment, the light-emitting-element section 30 includes the twelve areas 35 as illustrated in FIG. 1.

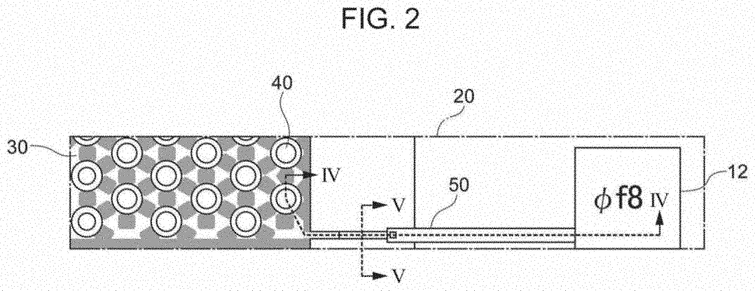

FIG. 2 is an enlarged explanatory view illustrating a region indicated by reference sign 20 in FIG. 1. A signal line 50 is formed between the gate electrodes 12 and the light-emitting-element section 30. The signal line 50 transmits signals for causing the light emitting elements 40 to emit light, to anode electrodes of the light emitting elements 40. In the present exemplary embodiment, the potential of the signal line 50 is the same regardless of the distances from the light emitting elements 40. Further, in the present exemplary embodiment, as illustrated in FIG. 1, the signal line 50 may be arranged between the areas 35 in the light-emitting-element section 30. In other words, in plan view of the light-emitting-element section 30, portions of the signal line 50 extending from the gate electrodes 12 do not overlap the areas 35 except for portions connected to the light emitting elements 40 in the areas 35, and are arranged within a gap for partitioning the areas 35. The width of the signal line 50 in a short-side direction may be smaller than the width of each area 35 of the light-emitting-element section 30 in plan view. The light emitting chip 10 according to the present exemplary embodiment has a so-called monolithic structure in which the light emitting elements 40 and the signal line 50 are formed in the same substrate.

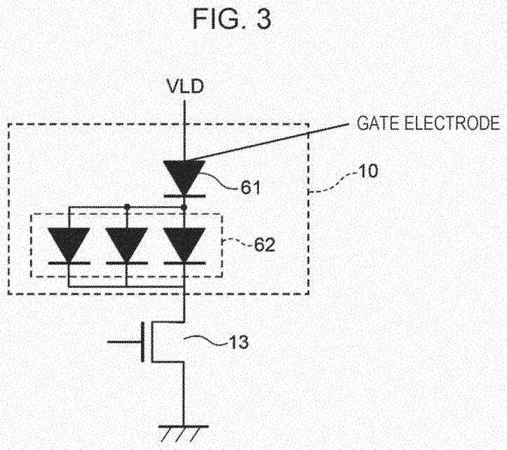

FIG. 3 is a circuit diagram. illustrating an equivalent circuit of the light emitting chip 10 illustrated in FIG. 1. The light emitting chip 10 includes a thyristor 61 and a light-emitting-diode portion 62. The thyristor 61 and the light-emitting-diode portion 62 correspond to each light emitting element 40. An anode of the thyristor 61 is electrically connected to the anode electrode 11, and a gate thereof is electrically connected to the gate electrode 12. Light emission of the light-emitting-diode portion 62 is controlled by a driver 13 electrically connected to a cathode electrode of the light emitting chip 10.

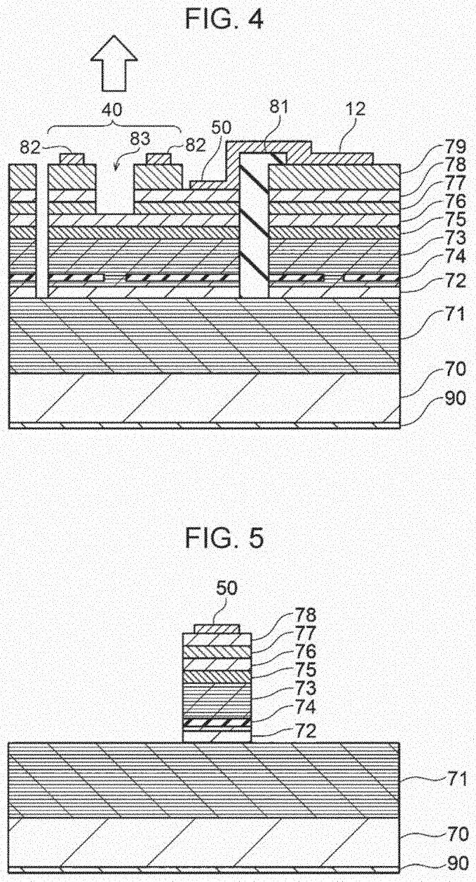

FIG. 4 is a sectional view illustrating a sectional structure taken along line IV-IV indicated. in FIG. 2. FIG. 5 is a sectional view illustrating a sectional structure taken along line V-V indicated in FIG. 2.

As illustrated in FIGS. 4 and 5, the light emitting chip 10 includes an n-type substrate 70 using GaAs, a lower distributed Bragg reflector (DBR) layer 71 formed on the n-type substrate 70, a resonator 72 formed on the lower DBR layer 71, an upper DBR layer 73 formed on the resonator 72, a tunnel coupling layer 75 formed on the upper DBR layer 73, a cathode layer 76 formed on the tunnel coupling layer 75, a p-gate layer 77 formed on the cathode layer 76, an n-gate layer 78 formed on the p gate layer 77, and an anode layer 79 formed on the n-gate layer 78. Moreover, a cathode electrode 90 (back surface electrode) is formed on a back surface of the n-type substrate 70. Further, the gate electrode 12 is formed on the anode layer 79.

The lower DBR layer 71 is a multilayer-film reflecting mirror formed by alternately and repeatedly stacking two semiconductor layers each having a predetermined film thickness of, for example, 0.25 λ/n, where λ is an oscillation wavelength of the light emitting element 40 and n is a refractive index of a medium (semiconductor layer), and having different refractive indices. In the present exemplary embodiment, the lower DBR layer 71 is of n-type.

The upper DBR layer 73 is a multilayer-film reflecting mirror formed by alternately and repeatedly stacking two semiconductor layers each having a predetermined film thickness of, for example, 0.25 λ/n, and having different refractive indices. In the present exemplary embodiment, the upper DBR layer 73 is of n-type.

The resonator 72 resonates and amplifies light emitted by the light emitting element 40. The light resonated and amplified by the resonator 72 is emitted. from an opening 83 of the light emitting element 40.

The cathode layer 76, the p-gate layer 77, the n-gate layer 78, and the anode layer 79 correspond to the thyristor 61 in the equivalent circuit illustrated in F That is, the cathode layer 76 functions as a cathode, the n-gate layer 78 functions as a gate, and the anode layer 79 functions as an anode.

In a region of the light. emitting element 40, the p-gate layer 77, the n-gate layer 78, and the anode layer 79 are removed by etching to form the opening 83. An anode electrode 82 is formed on the anode layer 79, adjacently to the opening 83.

An insulating layer 81 is formed between the region of the light emitting element 40 and a region of the adjacent gate electrode 12 so as to separate the sections including the resonator 72 to the anode layer 79 constituting both regions, from each other. The signal line 50 for transmitting a signal to the light emitting element 40 is formed from above the n-gate layer 78 toward the gate electrode 12 across the insulating layer 81 in a planar direction.

In the region of the light emitting element 40, an oxide region 74 is formed in the upper DBR layer 73. Since the oxide region 74 is formed in the region of she light emitting element 40, a current flowing from the anode electrode 82 toward the cathode electrode 90 may be decreased. By decreasing the current flowing from the anode electrode 82 toward the cathode electrode 90, power consumption of the light emitting chip 10 is decreased as compared to a case where the oxide region 74 is not formed.

In the present exemplary embodiment, a portion up to at least a region where the oxide region 74 is to be formed is exposed by etching, and a portion of the upper DBR layer 73 is oxidized to form the oxide region 74.

Similarly, in a region where the signal line 50 is formed, the oxide region 74 is formed over the entire area in the upper DBR layer 73 between the n-type substrate 70 and the signal line 50 in the present exemplary embodiment. The oxide region 74 is an example of an insulator according to an exemplary embodiment of the present disclosure, or particularly an example of an oxide film, and has a function of blocking a current. The oxide region 74 for insulation is formed over the entire area in. the upper DBR layer 73 in the region where the signal line 50 is formed. In this case, when a leakage current from the light emitting element 40 flows to the region where the signal line 50 is formed, if there is no oxide region 74, there is a possibility that the upper DBR layer 73 and the lower DBR layer 71 of the signal line 50 emit light. Since the current is consumed when the light is emitted, a leakage current flows more to the signal line 50 side. Further, even though the upper DBR layer 73 and the lower DBR layer 71 do not emit light, the current may escape to the lower layer side of the n-type substrate 70. Also when the current escapes to the lower layer side of the n-type substrate 70, a leakage current flows more to the signal line 50 by the amount. of the escape. In the present exemplary embodiment, even when a leakage current flows, the amount of the current decreases and the current that may be used for light emission increases, as compared to a case where the oxide region 74 is not formed in the region where the signal line 50 is formed and light is emitted in the region where the signal line 50 is formed or the current escapes to another place from the region where the signal line 50 is formed. In other words, in the present exemplary embodiment, light emission efficiency is improved as compared to the case where the oxide region 74 is not formed in the region where the signal line 50 is formed.

Depending on the oxidation process or the size of the region where the light emitting element 40 is formed or the region where the gate electrode 12 is formed, the entire region where the signal line 50 is formed does not necessarily overlap the oxide region 74 formed in the upper DBR layer 73 in plan view of the light emitting chip 10. The oxide region 74 does not have to overlap the entire surface of the signal line 50. That is, the oxide region 74 may be formed in a portion of the region where the signal line 50 is formed. Since the oxide region 74 is formed so as to overlap the portion of the region where the signal line 50 is formed, even when a leakage current from the light. emitting element 40 flows, the leakage current from the light emitting element 40 unlikely flows to the region where the signal line 50 is formed. In the present exemplary embodiment, oxide confinement is formed not only around the opening 83 for light emission but also in a portion along the signal line 50. In addition, for example, unlike a configuration in which a signal line is simply disposed on an insulating layer, the oxide region 74 is formed in a direction in which the signal line 50 is formed from the light emitting element 40 toward the gate electrode 12 when viewed from an upper surface of the light emitting chip 10.

### Second Exemplary Embodiment.

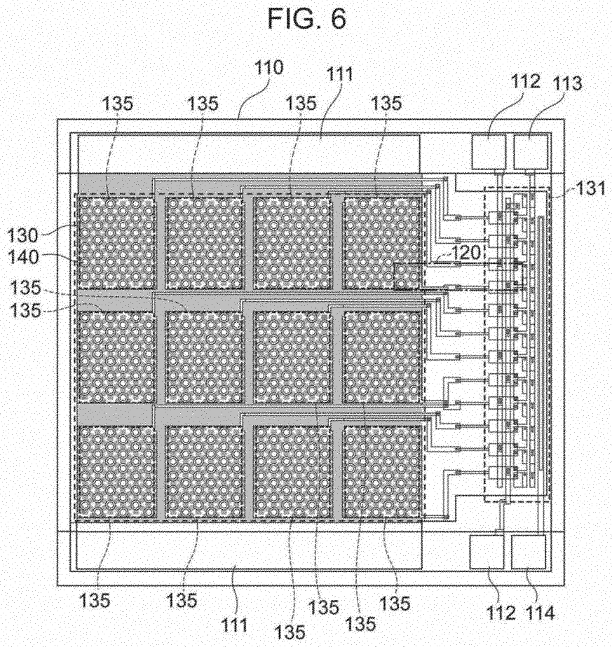

FIG. 6 is an explanatory plan view illustrating a light emitting chip according to a second exemplary embodiment of the present disclosure. A light emitting chip 110 illustrated in FIG. 6 includes an anode electrode 111, a gate electrode 112, a Vga terminal 113, a Vsub terminal 114, a light-emitting-element section 130, and a transfer circuit 131. The light-emitting-element section 130 includes plural light emitting elements 140.

The anode electrode 111 is an anode-side electrode formed in a portion of a wire extending from an anode electrode formed in the light-emitting-element section 130. The anode electrode 111 applies a predetermined voltage VLD to the light-emitting-element section 130. In the present. exemplary embodiment, an exemplary mode in which anode electrodes 111 are provided at both ends of the light emitting chip 110 will be described; however, the present disclosure not limited. to the mode, and an appropriate number of anode electrodes 111 may be provided in consideration of mounting or the like of the light emitting chip 110.

The gate electrode 112 is an electrode that supplies a signal for causing each light emitting element 140 of the light-emitting-element section. 130 to emit light. In the present exemplary embodiment, as will be described later, the light-emitting-element section 130 includes twelve areas 135 as illustrated in FIG. 6. Thus, the light emitting chip 110 illustrated in FIG. 6 includes twelve gate electrodes 112 to allow the light emitting elements 140 of each area 135 to independently emit light. The light emitting elements 140 emit light with a current supplied to the anode electrodes 111, and hence power required for light emission is supplied to the anode electrodes 111. In contrast, signals for light emission are supplied to the gate electrodes 112, and hence the voltage that is supplied to the gate electrodes 112 is smaller than the voltage that is supplied to the anode electrodes 111. Specifically, the voltage that is supplied to the gate electrodes 112 may be about 5 V to 10 V. The arrangement pattern of the gate electrodes 112 is not limited to the example illustrated in FIG. 6. The number of areas 135 is not limited to twelve.

The light-emitting-element section 130 includes the plural light emitting elements 140. In the present exemplary embodiment, the light-emitting-element section 130 corresponds to a region chat covers all the light emitting elements 110 formed on the light emitting chip 110. In the present exemplary embodiment, as in FIG. 1, an exemplary mode in which the light emitting elements 140 are arranged in a staggered form is provided; however, the present disclosure is not limited to the mode, and the light emitting elements 110 may be disposed, for example, in an array form. The number of light emitting elements 140 may be an appropriate number in consideration of output power or the like required for the light emitting chip 110. In the present exemplary embodiment, the light-emitting-element section 130 includes the twelve areas 135 as illustrated in. FIG. 6.

Unlike the light emitting chip 10 illustrated. in FIG. 1, the light emitting chip 110 illustrated in FIG. 6 includes the transfer circuit 131, and the Vga terminal 113 and the Vsub terminal 114 connected to the transfer circuit 131. The transfer circuit 131 is a circuit for supplying a transfer signal to the light-emitting-element section 130. The transfer signal is a. signal having two potentials of “H” and “L”. The light-emitting-element section 130 changes between a light emitting state and a non-light emitting state based on the transfer signal supplied from the transfer circuit 131.

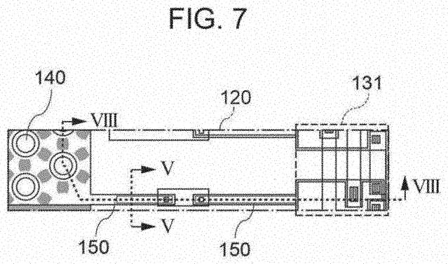

FIG. 7 is an enlarged explanatory view illustrating a region indicated by reference sign 120 in FIG. 6. In the present exemplary embodiment, the potential of a signal line 150 is the same regardless of the distances from the light emitting elements 140. Further, in the present exemplary embodiment, the signal line 150 may be arranged between the areas 135 in the light-emitting-element section 130. In other words, in plan view of the light-emitting-element. section 130, portions of the signal line 150 extending from the gate electrodes 112 do not overlap the areas 135 except for portions connected to the light. emitting elements 140 in the areas 135, and are arranged within a gap for partitioning the areas 135. Further, in the present exemplary embodiment, the signal line 150 may be arranged between the areas 135 in the light-emitting-element section 130, The width of the signal line 150 in a short-side direction may be smaller than the width of each area 135 of the light-emitting-element section 1.30 in plan view. The light emitting chip 110 according to the present exemplary embodiment has a so-called monolithic structure in which the light emitting elements 140 and the signal line 150 are formed in the same substrate.

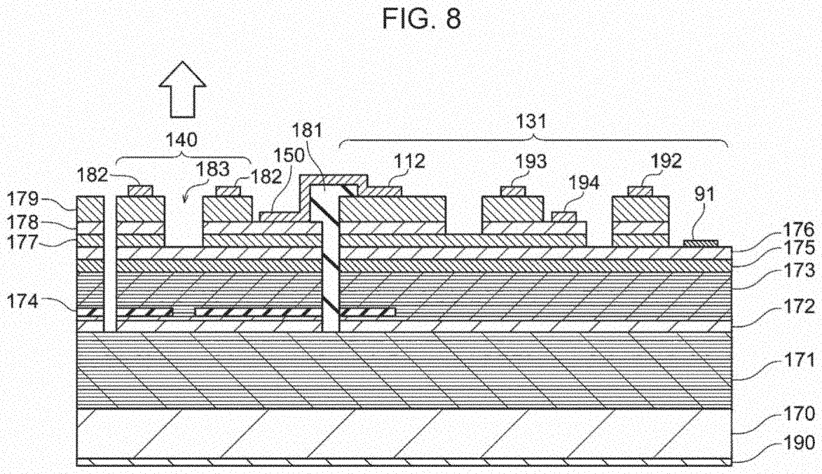

FIG. 8 is a sectional view illustrating a sectional structure taken along line VIII-VIII indicated in FIG. 7. The sectional structure taken along line V-V illustrated in

FIG. 7 is the same as the sectional structure illustrated in FIG. 5.

As illustrated in FIG. 8, the light emitting chip 110 includes an n-type substrate 170 using GaAs, a lower DBR layer 171 formed. on the n-type substrate 170, a resonator 172 formed on the lower DBR layer 171, an upper DBR layer 173 formed on the resonator 172, a tunnel coupling layer 175 formed on the upper DBP. layer 173, a cathode layer 176 formed on the tunnel coupling layer 175, a p-gate layer 177 formed on the cathode layer 176, an n-gate layer 178 formed on the p-gate layer 177, and an anode layer 179 formed on the n-gate layer 178. Moreover, a cathode electrode 190 (back surface electrode) is formed on a back. surface of the n-type substrate 170. Further, the gate electrode 112 is formed on the anode layer 179.

The lower DBR layer 171 is a multilayer-film reflecting mirror formed by alternately and repeatedly stacking two semiconductor layers each having a predetermined film thickness of, for example, 0.25 λ/n, where λ is an oscillation wavelength of the light emitting element 140 and n is a refractive index of a medium (semiconductor layer), and having different refractive indices. In the present exemplary embodiment, the lower DBR layer 171 is of n-type.

The upper DBR layer 173 is a multilayer-film reflecting mirror formed by alternately and repeatedly stacking two semiconductor layers each having a predetermined film thickness of, for example, 0.25 λ/n, and having different refractive indices. In the present exemplary embodiment, the upper DBR layer 173 is of n-type.

The resonator 172 resonates and amplifies light emitted by the light emitting element 140. The light resonated and amplified by the resonator 172 is emitted from an opening 183 of the light emitting element 140.

The cathode layer 176, the p-gate layer 177, the n-gate layer 178, and the anode layer 179 correspond to the thyristor 61 in the equivalent circuit illustrated in FIG. 3. That is, the cathode layer 176 functions as a cathode, the n-gate layer 178 functions as a gate, and the anode layer 179 functions as an anode.

In a region of the light emitting element 140, the p-gate layer 177, the n-gate layer 178, and the anode layer 179 are removed by etching to form the opening 183. An anode electrode 182 is formed. on. the anode layer 179, adjacently to the opening 183.

An insulating layer 181 is formed between the region of the light emitting element. 140 and a region of the adjacent gate electrode 112 so as to separate the sections including the resonator 172 to the p-gate layer 177 constituting both regions, from each other. The signal line 150 for transmitting a signal to the light emitting element 140 is formed from above the p-gate layer 177 to above the anode layer 179 to constitute the gate electrode 112 across the insulating layer 181 in a planar direction.

In the region of the light emitting element 140, an oxide region 174 is formed in the upper DBR layer 173. The oxide region 174 has a function of blocking a current. That is, by forming the oxide region 174 in the region of the light emitting element 140, a current. flowing from the anode electrode 182 toward the cathode electrode 190 may be decreased. By decreasing the current flowing from the anode electrode 182 toward the cathode electrode 190, power consumption of the light emitting chip 110 is decreased as compared to a case where the oxide region 174 is not formed.

In the present exemplary embodiment, a portion up to at least a region where the oxide region 174 is to be formed is exposed by etching, and a portion of the upper DBR layer 173 is oxidized to form The oxide region 174.

Similarly, in a region where the signal line 150 is formed, for example, the oxide region 174 is formed over the entire area in the upper DBR layer 173 between the n-type substrate 170 and the signal line 150. Since the oxide region 174 is formed. over the entire area in the upper DBR layer 173 in the region where the signal line 150 is formed, it is possible to prevent a leakage current from the light emitting element 140 from flowing to the region where the signal line 150 is formed.

Depending on the oxidation process or the size of the region where the light emitting element 140 is formed or the region where the gate electrode 112 is formed, the entire region where the signal line 150 is formed does not necessarily overlap the oxide region 174 formed in the upper DBR layer 173 in plan view of the light emitting chip 110. The oxide region 171 does not have to overlap the entire surface of the signal line 150. That is, the oxide region 174 may be formed in the upper DBR layer 173 in a portion of the region where the signal line 150 is formed. Since the oxide region 174 is formed in the upper DBR layer 173 so as to overlap the portion of the region where the signal line 150 is formed, even when a leakage current from the light emitting element 140 flows, the leakage current from the light emitting element 140 unlikely flows to the region where the signal line 150 is formed.

In each of the exemplary embodiments described above, the n-type substrate 70 or 170 using GaAs is provided; however, the present disclosure is not limited to such an example, and a p-type substrate may be used.

In the above-described first exemplary embodiment, a signal is transmitted between the gate electrode 12 and the light-emitting-element section 30 through the signal line 50 having the same potential. However, for example, another line other than the signal line 50 or a resistor may be formed between the gate electrode 12 and the light-emitting-element section 30. At this time, when there is a possibility that a leakage current from the light emitting element 40 is transmitted to the other line other than the signal line 50 or the resistor, or when a loss of light emission or the like is likely to occur, it is better to apply an oxide film to a lower portion of the other line or the resistor. In this case, the region to which the oxide film is applied may be the entire surface of a region of the other line other than the signal line 50 or the resistor, or may be only a portion thereof. For example, when the resistor is inserted in the middle of the signal line 50 and the resistor is located at a position where light is easily emitted from the portion of the resistor rather than from the signal line 50 or where the influence of light emission is large, the oxide film may be formed around the resistor.

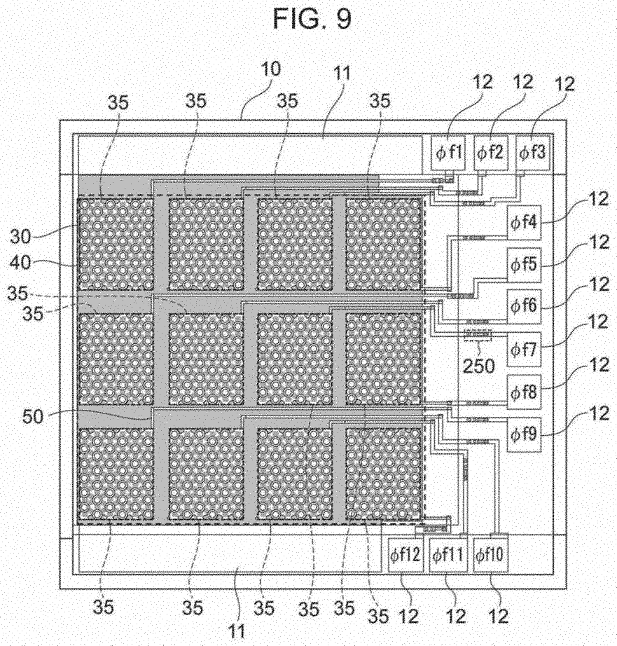

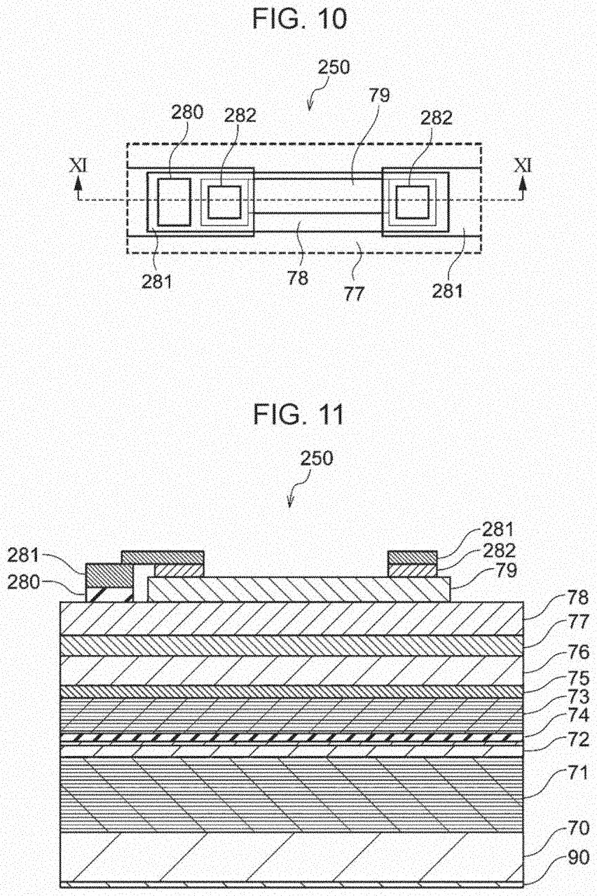

FIG. 9 is a plan view of the light emitting chip 10 in which a resistor 250 is formed in the middle of the signal line 50. The resistor 250 limits a current flowing from the gate electrode 12 to the light-emitting-element section 30. FIG. 10 is an enlarged view illustrating the resistor 250. FIG. 11 is a sectional view illustrating a sectional structure taken along line XI-XI of FIG. 10. An electrode 282 is formed on the anode layer 79, and a connection wire 281 is connected to the electrode 282. An insulating film 280 is formed between the connection wire 281 and the n-gate layer 78. In the resistor 250, the anode layer 79, the connection wire 281, and the electrode 282 function as a signal line. The anode layer 79 serves as a resistor for limiting a current flowing from the gate electrode 12 to the light-emitting-element section 30.

When a leakage current from the light emitting element 40 flows into a region of the resistor 250 through the lower DBR layer 71 in a state in which the oxide region 74 is not formed in the region of the resistor 250, the region of the resistor 250 is erroneously lit. This is because the resistor 250 has a thyristor structure. The region of the resistor 250 includes at least a region where the anode layer 79 is formed. That is, a region capable of emitting light according to an exemplary embodiment of the present disclosure includes at least the region where the anode layer 79 is formed. Thus, in the light emitting chip 10 according to the present. exemplary embodiment, the oxide region 74 is formed in the upper DBR layer 73 in the region where the resistor 250 is formed. The oxide region 74 is formed, for example, by oxidizing the upper DBR layer 73 from a side surface on a side orthogonal to line XI-XI of the region of the resistor 250.

Since the oxide region 74 is formed in the upper DBR. layer 73 in the region where the resistor 250 is formed, a leakage current from the light emitting element 40 through the lower DBR layer 71 may be prevented from flowing to the cathode layer 76, the p-gate layer 77, the n-gate layer 78, and the anode layer 79 in the region where the resistor 250 is formed.

The oxide region 74 may be formed in a region where the p-gate layer 77 is formed, in addition to a region of the n-gate layer 78 illustrated in FIG. 10. Since the oxide region 74 is also formed in the region where the p-gate layer 77 is formed, it is possible to more reliably prevent a leakage current from the light emitting element 40 from flowing into the region of the resistor 250.

Next, a specific example of an apparatus in which the light emitting chip according to the first exemplary embodiment or the second exemplary embodiment is used will be described.

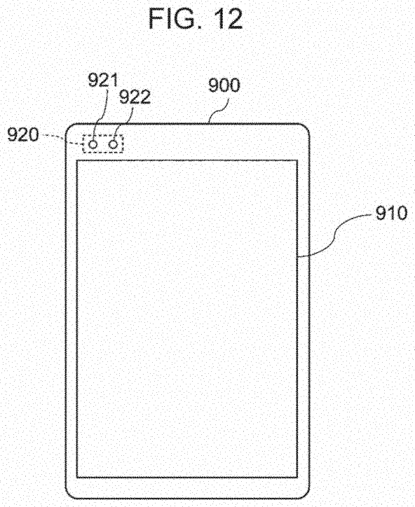

FIG. 12 illustrates an outline of a smartphone 900 in which the light emitting chip according to the first exemplary embodiment or the second exemplary embodiment of the present disclosure is used. The smartphone 900 includes a display 910 that displays information and a distance measurer 920 that measures a distance to an object. smartphone 900 is an example of an optical measurement apparatus according to an exemplary embodiment of the present disclosure.

The distance measurer 920 measures a distance between the smartphone 900 and an object of a distance measurement target by a Time of Flight (MF) method. The distance measurer 920 includes a light emitter 921 and a light receiver 922. The light emitter 921 radiates light toward the distance measurement target. The light emitter 921 is provided with, for example, the light emitting chip 10 according to the first exemplary embodiment or the light emitting chip 110 according to the second exemplary embodiment. The light receiver 922 receives light emitted by the light emitter 921 and reflected by the object of the distance measurement target. The light receiver 922 is provided with, for example, a complementary metal-oxide semiconductor (CMOS) image sensor.

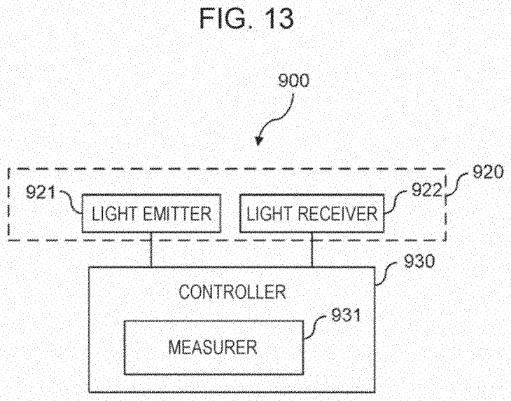

FIG. 13 illustrates a functional configuration example of the smartphone 900. A controller 930 includes, for example, a central processing unit (CPU), a read only memory (ROM) , a random access memory (RAM) and controls operation of the smartphone 900. The controller 930 operates as a measurer 931 by reading and executing a control program provided in the ROM.

The measurer 931 controls the light emitter 921 to emit light from the light emitter 921 in a short period. That is, the light emitter 921 emits pulsed light under the control of the measurer 931. The measurer 931 measures the distance to the object by the Time of Flight method based on the flight distance of light emitted from the light emitter 921 and received by the light receiver 922. More specifically, the measurer 931 calculates an optical path. length from when light is emitted by the light emitter 921 to when the light is reflected by the object of the distance measurement target and reaches the light receiver 922, based on a time difference between a time point at which the light emitter 921 emits the light and a time point at which the light receiver 922 receives the reflected light from the object of the distance measurement target. The positions of the light emitter 921 and the light receiver 922 and the gap between the light emitter 921 and the light receiver 922 are determined in advance. Thus, the measurer 931 may measure the distance from the light emitter 921 and the light receiver 922 to the object of the distance measurement target.

The smartphone 900 may obtain the distance to the object of the distance measurement target by measuring the time until the light emitted by the light emitter 921 is reflected by the object of the distance measurement target and received by the light receiver 922.

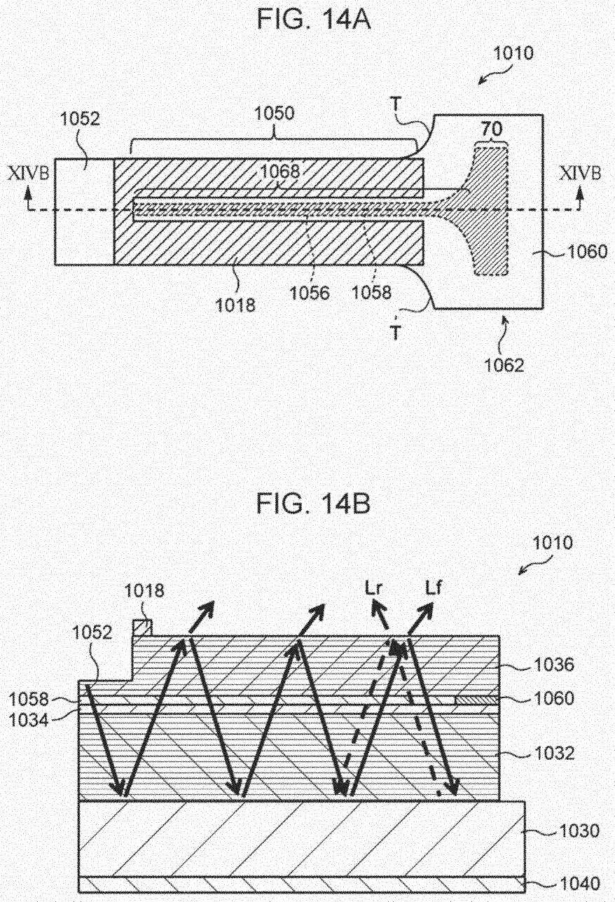

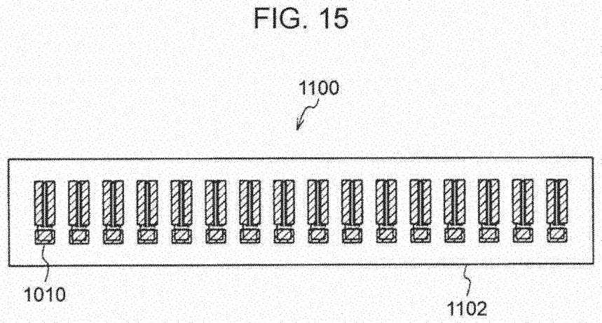

In the above-described first exemplary embodiment, the light emitting chip 10 that radiates light in the vertical direction is provided; however, the present disclosure is not limited to the example. For example, the present disclosure may be applied to a light emitting element. 1010 that emits light in a direction Lf that intersects with a substrate surface and that is inclined forward in a propagation direction of propagation light. in a propagation light waveguide as illustrated in FIGS. 14A and 14B, and a light emitting device 1100 in. which. plural light emitting elements 1010 that radiate light in the direction Lf are provided on a substrate 1102 as illustrated in. FIG. 15.

The light emitting element 1010 illustrated in plan view of FIG. 14A and a sectional view of FIG. 14B taken along line XIVB-XIVB of FIG. 14A. includes an optical amplifying portion 1050, a widened portion 1062, and an optical coupling portion 1052. The optical amplifying portion 1050 has a function of amplifying light (seed light) coupled to the optical coupling portion 1052 and emitting the amplified light. The optical amplifying portion 1050 is, for example, a surface-emitting optical amplifying portion using a GaAs-based DBR waveguide. That is, the optical amplifying portion 1050 includes an N electrode 1040 that is formed on a back surface of a substrate 1030, and a lower DBR 1032, an active region 1034, an upper DBR 1036, a non-conductive region 1060, a conductive region 1058, and a P electrode 1018 that are formed on or above the substrate 1030.

In the above-described first exemplary embodiment, the oxide region 74 is formed in the upper DBR layer 73 of the signal line 50 for insulation, so that the oxide confinement may be formed in the same process as the oxide confinement in the light-emitting-diode portion 62. However, an oxide region may be provided in another layer instead of the upper DBR layer 73.

Although the thyristor 61 is provided on the light-emitting-diode portion 62 in the above-described first exemplary embodiment, the light-emitting-diode portion 62 may be provided on the thyristor 61. In the case where the light-emitting-diode portion 62 is provided on the thyristor 61, the oxide region 74 of the signal line 50 is provided in the upper DBR layer 73, so that a current does not pass through a layer having a large loss due to light emission.

Tn the above-described first exemplary embodiment, the oxide region 74 is applied to the signal line 50 that supplies a signal to the gate layer of the thyristor 61. However, an oxide region may be applied to a signal line that is without the thyristor 61 and that supplies a signal to the light-emitting-diode portion 62. In this case, for the signal line 50, the supply of a signal for light emission and the supply of a current for light emission may be considered as the same, and the light-emitting-diode portion 62 may be configured to emit light at a timing at which a current is supplied. In the above-described first exemplary embodiment, the example in which the oxide confinement is also formed in the light-emitting-diode portion 62 has been described. However, the oxide confinement may be formed only for the signal line 50 without providing the oxide confinement in the light-emitting-diode portion 62.

In the above-described first exemplary embodiment, the simple example in which the signal line 50 is formed between the gate electrode 12 and the light-emitting-element section 30 has been described. However, in a case where the periphery of the signal line 50 has a more complicated structure, it may be difficult to clarify to what extent the signal line 50 is located. Unless it is clear to what extent the signal line 50 is located, it is not easy to determine to what extent the oxide confinement is to be provided. In the case where the periphery of the signal line 50 has a more complicated structure, for example, a portion having the same potential in the vicinity of the light emitting element 40 continuing from. the signal line 50 in the vicinity of the light emitting element 40 may be used as the signal line 50, and the oxide confinement may be provided at least in the lower surface of the portion having the same potential.

Although the oxide film is used as the insulating layer in the above-described exemplary embodiments, the oxide film described. in the above-described exemplary embodiments may be replaced by another measure such as ion implantation for insulation as long as insulation is provided.

### Third Exemplary Embodiment

Next, another exemplary embodiment of the present disclosure will be described with reference to the drawings. In the drawings, the same or equivalent components and portions are denoted by the same reference numerals. The dimensional ratios in the drawings are exaggerated for convenience of explanation, and may be different from actual ratios.

Hereinafter, an exemplary mode in which a vertical cavity surface emitting laser (VCSEL) is applied as a light emitting element according to an exemplary embodiment of the present disclosure will be described; however, the present disclosure is not limited thereto, and an exemplary mode in which a light emitting diode (LED) or the like is applied may be employed.

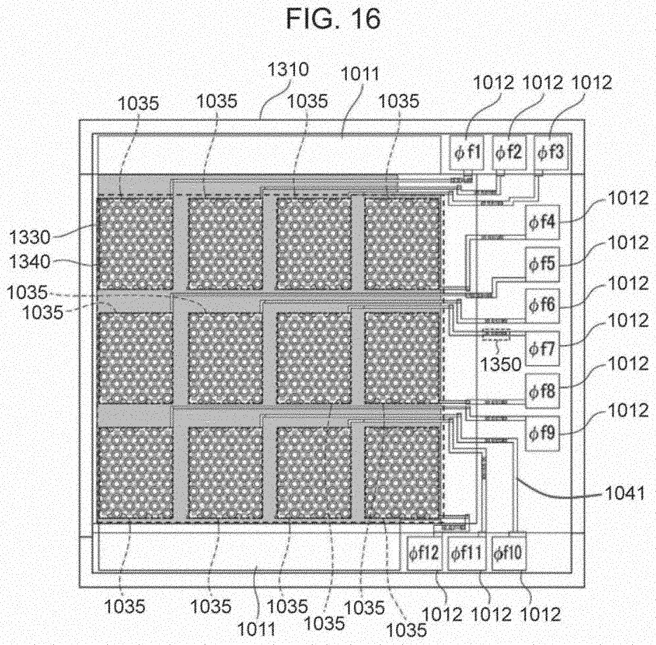

FIG. 16 is an explanatory plan view Illustrating a light emitting chip according to a third exemplary embodiment of the present disclosure. A light emitting chip 1310 illustrated in FIG. 16 includes an anode electrode 1011, a gate electrode 1012, and a light-emitting-element section 1300. The light-emitting-element section 1330 includes plural light emitting elements 1340.

The anode electrode 1011 is an anode-side electrode formed in a portion of a wire extending from an anode electrode formed. in the light-emitting-element section 1330. The anode electrode 1011 applies a predetermined voltage VLD to the light-emitting-element section 1330. In the present exemplary embodiment, an exemplary mode in which anode electrodes 1011 are provided at. both ends of the light emitting chip 1310 will be described; however, the present disclosure is not limited to the mode, and an appropriate number of anode electrodes 1011 may be provided in consideration of mounting or the like of the light emitting chip 1310.

The gate electrode 1012 is an example of a terminal to which a signal to be transmitted to a light emitting element according to an exemplary embodiment of the present disclosure is input, and is an electrode that supplies a signal for causing the light-emitting-element section 1330 to emit light, to the light-emitting-element section 1330 through a signal line 1041. In the present exemplary embodiment, as will be described later, the light-emitting-element section 1330 includes twelve areas 1035 as illustrated in FIG. 16. Thus, the light emitting chip 1310 illustrated in FIG. 16 includes twelve gate electrodes 1012 to allow the light emitting elements 1340 of each area 1035 to independently emit light. The light emitting elements 1340 emit light with a current supplied to the anode electrodes 1011, and hence power required for light emission is supplied to the anode electrodes 1011. In contrast, signals for light emission are supplied to the gate electrodes 1012, and hence the voltage that is supplied to the gate electrodes 1012 is smaller than the voltage that is supplied to the anode electrodes 1011. Specifically, the voltage that is supplied to the gate electrodes 1012 may be about 5 V to 10 V. The arrangement pattern of the gate electrodes 1012 s not limited to the example illustrated in FIG. 16. The number of areas 1035 is not limited to twelve.

The light-emitting-element section 1330 includes the plural light emitting elements 1340. In the present exemplary embodiment, the light-emitting-element section 1330 corresponds to a region that covers all the light emitting elements 1340 formed on the light emitting chip 1310. In the present exemplary embodiment, assuming that an up-down direction of FIG. 16 indicates a row, the light emitting elements 1340 arranged in each row are arranged at a predetermined interval. In contrast, when viewed in a left-right direction of FIG. 16, the light emitting elements 1340 are arranged at a predetermined interval in every other row. Adjacent rows are shifted in the up-down direction by half the size of each light emitting element 1340, and hence the light emitting elements 1340 are arranged in a so-called staggered form. However, the arrangement of the light emitting elements 1340 is not limited to the staggered form, and for example, the light emitting elements 1340 may be arranged in a so-called array form in which the light emitting elements 1340 are arranged in each row at a predetermined interval and the positions of the light emitting elements 1340 in adjacent rows are not shifted in the up-down direction. The number of light emitting elements 1340 may be an appropriate number in consideration of output power or the like required for the light emitting chip 1310. In the present exemplary embodiment, the light-emitting-element section 1330 includes the twelve areas 1035 as illustrated in FIG. 16.

Further, in the present exemplary embodiment, as illustrated in FIG. 16, the signal line 1041 may be arranged between the areas 1035 in the light-emitting-element section 3300 In other words, in plan view of the light-emitting-element section 1330, portions of the signal line 1041 extending from the gate electrodes 1012 do not overlap the areas 1035 except for portions connected to the light emitting elements 1340 in the areas 1035, and are arranged within a gap for partitioning the areas 1035. The width of the signal line 1041 in a short-side direction may be smaller than the width of each area 1035 of the light-emitting-element section 1330 in plan view. The light emitting chip 1310 according to the present exemplary embodiment has a so-called monolithic structure in which the light emitting elements 1340 and the signal line 1041 are formed in the same substrate.

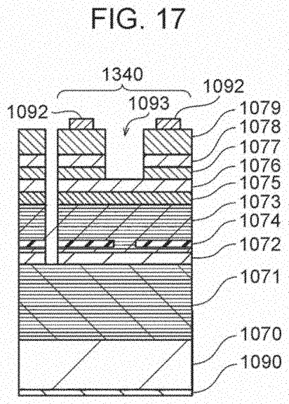

FIG. 17 is a sectional view illustrating a sectional structure of each light emitting element 1340.

The light emitting element 1340 includes an n-type substrate 1070 using GaAs, a lower distributed Bragg reflector (DBR) layer 1071 formed on the n-type substrate 1070, a resonator 1072 formed on the lower DBR layer 1071, an upper DBR layer 1073 formed on the resonator 1072, a tunnel coupling layer 1075 formed on the upper DBR layer 1073, a cathode layer 1076 formed on the tunnel coupling layer 1075, a p-gate layer 1077 formed on the cathode layer 1076, an n-gate layer 1078 formed on the p-gate layer 1077, and an anode layer 1079 formed on the n-gate layer 1078. Moreover, a cathode electrode 1090 (back surface electrode) is formed on a back surface of the n-type substrate 1070. Further, an anode electrode 1092 is formed on the anode layer 1079.

The lower DBR layer 1071 is a multilayer-film reflecting mirror formed by alternately and repeatedly stacking two semiconductor layers having a predetermined film thickness of, for example, 0.25 λ/n, where λ is an oscillation wavelength of the light emitting element 1340 and n is a refractive index of a medium. (semiconductor layer), and having different refractive indices. In the present exemplary embodiment, the lower DBR layer 1071 is of n-type.

The upper DBR layer 1073 is a multilayer-film reflecting mirror formed by alternately and repeatedly stacking two semiconductor layers each having a predetermined film thickness of, for example, 0.25 λ/n, and having different refractive indices. In the present exemplary embodiment, the upper DBR layer 1073 is of n-type.

The resonator 1072 resonates and amplifies light emitted by the light emitting element 1340. The light resonated and. amplified by the resonator 1072 is emitted from an opening 1093 of the light emitting element 1340.

The cathode layer 1076 functions as a cathode, the p-gate layer 1077 and. the n-gate layer 1078 function as a gate, and the anode layer 1079 functions as an anode.

In a region of the light emitting element 1340, the p-gate layer 1077, the n-gate layer 1078, and the anode layer 1079 are removed by etching to form the opening 1093. An anode electrode 1092 is formed on the anode layer 1079, adjacently to the opening 1093.

In the region of the light emitting element 1340, an oxide region 1074 is formed in the upper DBR layer 1073. The oxide region 1074 is an example of an insulating layer according to an exemplary embodiment of the present disclosure, or particularly an example of an oxide film, and has a function of blocking a current. That is, by forming the oxide region 1074 in the region of the light emitting element 1340, a current flowing from the anode electrode 1092 toward the cathode electrode 1090 may be decreased. By decreasing the current flowing from the anode electrode 1092 toward the cathode electrode 1090, power consumption of the light emitting chip 1310 is decreased as compared to a case where the oxide region 1074 is not formed.

In the present exemplary embodiment, a portion up to at. least a region where the oxide region 1074 is to be formed is exposed by etching, and a portion of the upper DBR layer 1073 is oxidized to form the oxide region 1074.

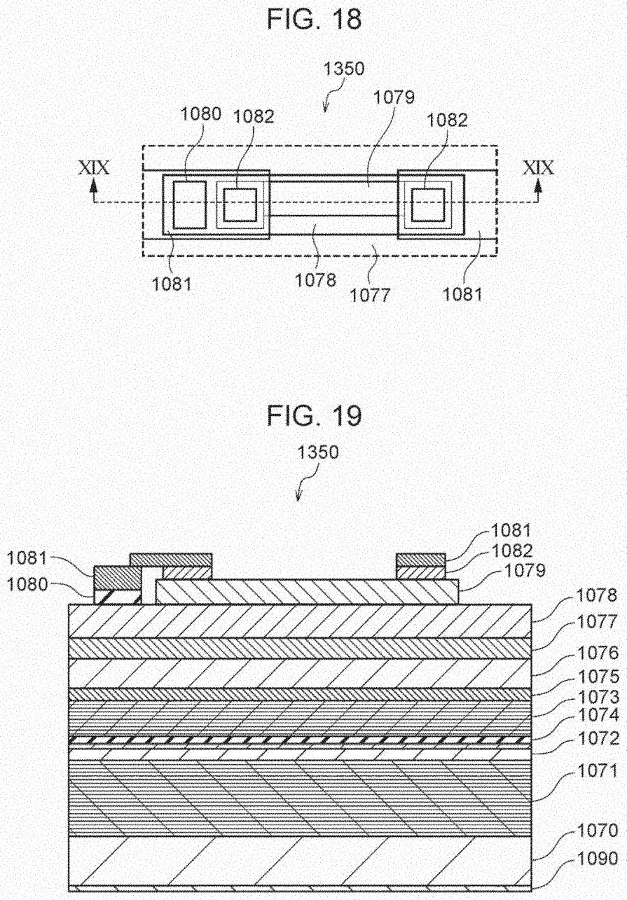

A resistor 1350 for limiting a current flowing from the gate electrode 1012 to the light-emitting-element section 1330 is formed in the middle of the signal line 1041 for transmitting a signal from the gate electrode 1012 to the light-emitting-element section. 1330. The resistor 1350 is formed between the gate electrode 1012 and the light-emitting-element section 1330. FIG. 18 is an enlarged view illustrating the resistor 1350. FIG. 19 is a sectional view illustrating a sectional structure taken along line XIX-XIX of FIG. 18.

The light emitting chip 1310 includes an n-type substrate 1070 using GaAs, a lower distributed Bragg reflector (DBR) layer 1071 formed on the n-type substrate 1070, a resonator 1072 formed on the lower DBR layer 1071, an upper DBR layer 1073 formed on the resonator 1072, a tunnel coupling layer 1075 formed on the upper DBR layer 1073, a cathode layer 1076 formed on the tunnel coupling layer 1075, a p-gate layer 1077 formed on the cathode layer 1076, an n-gate layer 1078 formed on the p-gate layer 1077, and an anode layer 1079 formed on the n-gate layer 1078. Moreover, a cathode electrode 1090 (hack surface electrode) is formed on a back surface of the n-type substrate 1070.

An electrode 1082 is formed on the anode layer 1079, and a connection wiring 1081 is connected to the electrode 1082. An insulating film 1080 is formed between the connection wiring 1081 and the n-gate layer 1078. In the resistor 1350, the anode layer 1079, the connection wiring 1081, and the electrode 1082 function as a signal line. The anode layer 1079 serves as a resistor for limiting a current flowing from the gate electrode 1012 to the light-emitting-element section 1330.

When a leakage current from the light emitting element 1340 flows into a region of the resistor 1350 through the lower DBR layer 1071 in a state in which the oxide region 1074 is not formed in the region of the resistor 1350, the region of the resistor 1350 is erroneously lit. This is because the resistor 1350 has a thyristor structure, The region of the resistor 1350 includes at least a region where the anode layer 1079 is formed. That is, a region capable of emitting light according to an exemplary embodiment of the present disclosure includes at least the region where the anode layer 1079 is formed. Thus, in the light emitting chip 1310 according to the present exemplary embodiment, the oxide region 1074 is formed in the upper DBR layer 1073 in the region where the resistor 1350 is formed. The oxide region 1074 is formed, for example, by oxidizing the upper DBR layer 1073 from a side surface on a side orthogonal to line XIX-XIX of the region of the resistor 1350.

Since the oxide region 1074 is formed in the upper DBR layer 1073 in the region where the resistor 1350 is formed, a leakage current from the light emitting element 1340 through the lower DBR layer 1071 may be prevented from. flowing to the cathode layer 1076, the p-gate layer 1077, the n-gate layer 1078, and the anode layer 1079 in the region where the resistor 1350 is formed.

In this case, when a leakage current from the light emitting element 1340 flows to a region where a resistor 1350 is formed, if there is no oxide region 1074, there is a possibility that the upper DBR layer 1073 and the lower DBR layer 1071 in the region where the resistor 1350 is formed emit light. Since the current is consumed when the light is emitted, a leakage current flows more to the resistor 1350 side. Further, even though the upper DBR layer 1073 and the lower DBR layer 1071 do not emit light, the current may escape to the lower layer side of the n-type substrate 1070. Also when the current escapes to the lower layer side of the n-type substrate 1070, a leakage current flows more to the region of the resistor 1350 by the amount oil the escape. In the present exemplary embodiment, even when a leakage current flows, the amount of the current decreases and the current that may be used for light emission increases, as compared to a case where the oxide region 1074 is not formed in the region where the resistor 1350 is formed and light is emitted in the region where the resistor 1350 is formed or the current escapes to another place from the region where the resistor 1350 is formed. In other words, in the present exemplary embodiment, light emission efficiency is improved as compared to the case where the oxide region 1074 is not formed in the region where the resistor 1350 is formed.

Depending on the oxidation process or the size of the region where the light emitting element 1340 is formed or the region where the gate electrode 1012 is formed, the entire region where the resistor 1350 is formed does not necessarily overlap the oxide region 1074 formed in the upper DBR layer 1073 in plan view of the light emitting chip 1310. The oxide region 1074 may not overlap the entire area in the region where the resistor 1350 is formed. That is, the oxide region 1074 may be formed in a portion of the region where the resistor 1350 is formed. Since the oxide region 1074 is formed so as to overlap the portion of the region where the resistor 1350 is formed, even when a leakage current from the light emitting element 1340 flows, the leakage current from the light emitting element 1340 unlikely flows to the region where the resistor 1350 is formed.

The oxide region 1074 may be formed in a region where the p-gate layer 1077 is formed, in addition to a region of the n-gate layer 1078 illustrated in FIG. 18. Since the oxide region 1074 is also formed in the region where the p-gate layer 1077 is formed, it is possible to more reliably prevent a leakage current from the light emitting element 1340 from flowing into the region of the resistor 1350.

Next, a specific example of an apparatus in which the light emitting chip according to the above-described exemplary embodiment is used will be described.

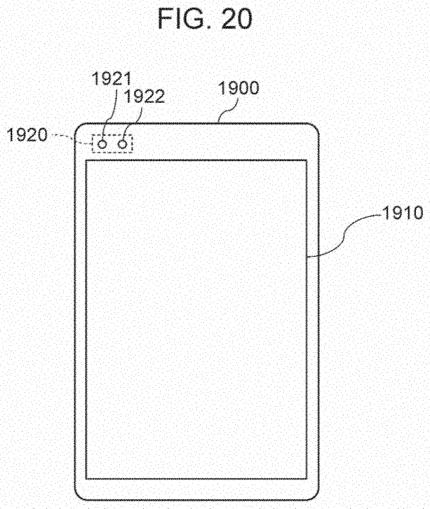

FIG. 20 illustrates an outline of a smartphone 1900 in which the light emitting chip according to the exemplary embodiment of the present disclosure is used. The smartphone 1900 includes a display 1910 that displays information and a distance measurer 1920 that measures a distance to an object. The smartphone 1900 is an example of an optical measurement apparatus according to an exemplary embodiment of the present disclosure.

The distance measurer 1920 measures a distance between the smartphone 1900 and an object of a distance measurement target by a Time of Flight (ToF) method. The distance measurer 1920 includes a light emitter 1921 and a light receiver 1922. The light emitter 1921 radiates light toward the distance measurement target. The light emitter 1921 is provided with, for example, the light emitting chip 1310 according to the third exemplary embodiment. The light receiver 1922 receives light emitted by the light emitter 1921 and reflected by she object of the distance measurement target. The light receiver 1922 is provided with, for example, a CMOS image sensor.

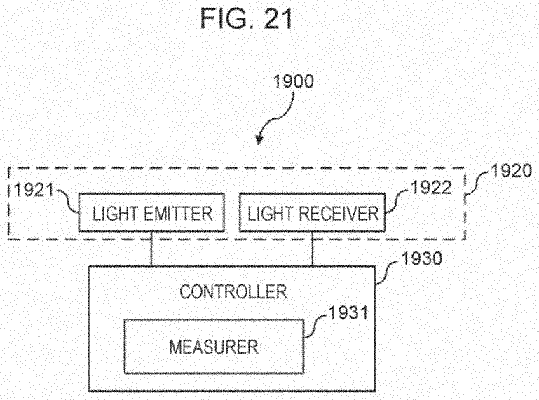

FIG. 21 illustrates a functional configuration example of the smartphone 1900. A controller 1930 includes, for example, a central processing unit (CPU), a read only memory (ROM), a random access memory (RAM) and controls operation of the smartphone 1900. The controller 1930 operates as a measurer 1931 by reading and executing a control program provided in the ROM.

The measurer 1931 controls the light emitter 1921 to emit light from the light emitter 1921 in a short period.

That is, the light emitter 1921 emits pulsed light under the control of the measurer 1931. The measurer 1931 measures the distance to the object by the Time of Flight method based on the flight distance of light emitted from the light emitter 1921 and received by the light receiver 1922. More specifically, the measurer 1931 calculates an optical path length from when light is emitted by the light emitter 1921 to when the light is reflected by the object of the distance measurement target and reaches the light receiver 1922, based on a time difference between a time point at which the light emitter 1921 emits the light and a time point at which the light receiver 1922 receives the reflected light from the object of the distance measurement target. The positions of the light emitter 1921 and the light receiver 1922 and the gap between the light emitter 1921 and the light receiver 1922 are determined in advance. Thus, the measurer 1931 may measure she distance from the light emitter 1921 and the light receiver 1922 to the object of the distance measurement target.

The smartphone 1900 may obtain the distance to the object of the distance measurement target by measuring the time until the light emitted by the light emitter 1921 is reflected by the object of the distance measurement target and received by the light receiver 1922.

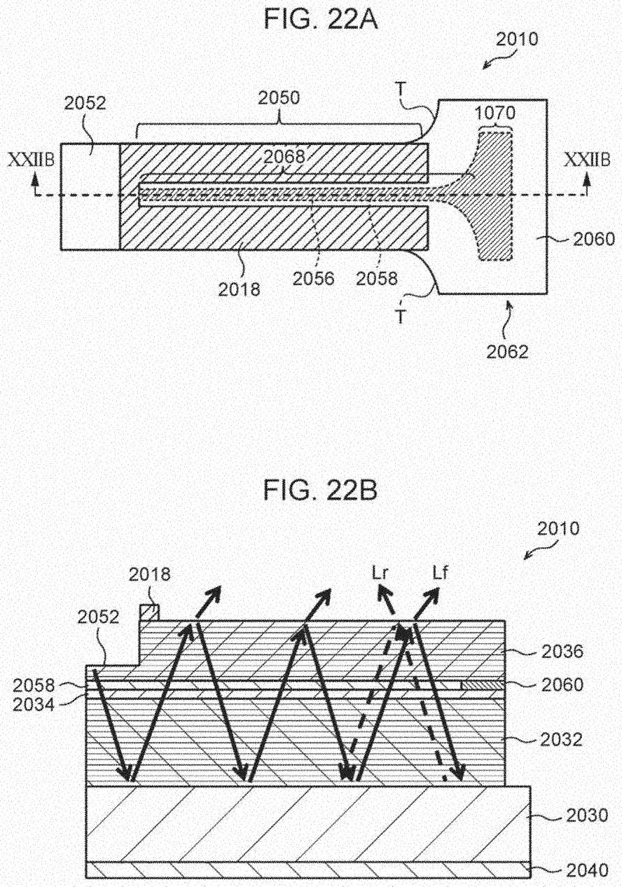

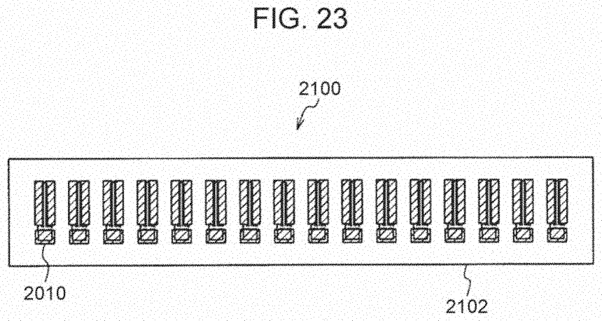

In the above-described exemplary embodiment, the light emitting chip 1310 that radiates light in the vertical direction is provided; however, the present disclosure is not. limited to the example. For example, the present disclosure may be applied to a light emitting element 2010 that radiates light in a direction LF that intersects with a substrate surface and that is inclined forward in a propagation direction of propagation light in a propagation light waveguide as illustrated in FIGS. 22A and 22B, and a light emitting device 2100 in which plural light emitting elements 2010 that emit light in the direction Lf are provided on a substrate 2102 as illustrated in FIG. 23.

The light emitting element 2010illustrated in plan view of FIG. 22A and a sectional view of FIG. 22B taken along line XXIIB-XXIIB of FIG. 22A includes an optical amplifying portion 2050, a widened portion 2062, and an optical coupling portion 2052. The optical amplifying portion 2050 has a function of amplifying light (seed light) coupled to the optical coupling portion 2052 and emitting the amplified light. The optical amplifying portion 2050 is, for example, a surface-emitting optical amplifying portion using a GaAs-based. DBR waveguide. That is, the optical amplifying portion 2050 includes an N electrode 2040 that is formed on a back surface of a substrate 2030, and a lower DBR 2032, an active region 2034, an upper DBR 2036, a non-conductive region 2060, a conductive region 2058, and a P electrode 2018 that are formed on or above the substrate 2030.

In the above-described exemplary embodiment, the oxide region 1074 is formed in the upper DBR layer 1073 of the resistor 1350 for insulation, so, that the oxide confinement may be formed in the same process as the oxide confinement in the light emitting element 1340. However, the oxide region. may be provided in another layer instead of the upper DBR layer 1073.

Although the oxide film is used. as the insulating layer in the above-described exemplary embodiment, the oxide film described in the above-described exemplary embodiment may be replaced by another measure such as ion implantation for insulation as long as insulation is provided.

Although the oxide region 1074 is formed for insulation in the region where the resistor 1350 is formed in the above-described exemplary embodiment, the oxide region 1074 may also be formed for insulation in a region where the signal line 1041 is formed.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A light emitting device, comprising:
a semiconductor substrate;
a light-emitting-element section formed on the semiconductor substrate and including a plurality of light emitting elements that radiate light;
a signal line that is formed on the semiconductor substrate and that transmits a signal to the light emitting elements; and
an oxide film formed between the signal line and the semiconductor substrate along an extension direction of the signal line.

2. The light emitting device according to claim 1, wherein the signal line transmits a signal from a terminal disposed in the semiconductor substrate to the light-emitting-element section.

3. The light emitting device according to claim 2, wherein a signal for causing the light emitting elements to emit light is transmitted from the terminal to the signal line.

4. The light emitting device according to claim 3, wherein the signal line has a same potential regardless of distances from the light emitting elements.

5. The light emitting device according to claim 1, wherein the light-emitting-element section includes a plurality of areas, and the light emitting elements are connected to the signal line in each of the areas.

6. The light emitting device according to claim 5, wherein the signal line is arranged between the areas.

7. The light emitting device according to claim 5, wherein a width of the signal line in a short-side direction is smaller than a width of each of the areas in plan view.

8. The light emitting device according to claim 1, wherein the oxide film is formed between the signal line and the semiconductor substrate over an entire region where the signal line is formed.

9. A light emitting device, comprising:
a semiconductor substrate;
a light-emitting-element section formed on the semiconductor substrate and including a plurality of light emitting elements that radiate light;
a signal line that is formed on the semiconductor substrate and that transmits a signal to the light emitting elements; and
an insulator formed between the signal line and the semiconductor substrate along the signal line.

10. An optical measurement apparatus, comprising:
the light emitting device according to claim 1;
a light receiver that receives light emitted from the light emitting device and reflected by an object; and
a measurer that measures a distance to the object based on a flight distance of light emitted from the light emitting device and received by the light receiver.

11. An optical measurement apparatus, comprising:
the light emitting device according to claim 2;
a light receiver that receives light emitted from the light emitting device and reflected by an object; and
a measurer that measures a distance to the object based on a flight distance of light emitted from the light emitting device and received by the light receiver.

12. An optical measurement apparatus, comprising:
the light emitting device according to claim 3;
a light receiver that receives light emitted from the light emitting device and reflected by an object; and
a measurer that measures a distance to the object based on a flight distance of light emitted from the light emitting device and received by the light receiver.

13. An optical measurement. apparatus, comprising:
the light emitting device according to clam 4;
a light receiver that receives light emitted from the light emitting device and reflected by an object; and
a measurer that measures a distance to the object based on a flight distance of light emitted from the light emitting device and received by the light receiver.

14. An optical measurement apparatus, comprising:
the light emitting device according to claim 5;
a light receiver that receives light emitted from the light emitting device and reflected by an object; and
a measurer that measures a distance to the object based on a flight distance of light emitted from the light emitting device and received by the light receiver.

15. An optical measurement apparatus, comprising:
the light emitting device according to claim 6;
a light receiver that receives light emitted from the light emitting device and reflected by an object; and
a measurer that measures a distance to the object based on a flight distance of light emitted from the light emitting device and received by the light receiver.

16. A light emitting device, comprising:
a semiconductor substrate;
a light-emitting-element section formed in a partial region. of the semiconductor substrate and including a plurality of light emitting elements that radiate light;
a signal line that is formed on the semiconductor substrate and that transmits a signal to the light emitting elements; and.
an insulating layer formed between the signal line and the semiconductor substrate in a region where the signal line is capable of emitting light.

17. The light emitting device according to claim 16, further comprising:
a resister that is formed in the region where the signal line is capable of emitting light and that limits a current to the light emitting elements,
wherein the insulating layer is formed. in a region of the resistor.

18. The light emitting device according to claim 17, wherein the insulating layer is further formed in a predetermined region around the region of the resistor.

19. The light emitting device according to claim 16, wherein the light-emitting-element section includes a plurality of areas, and the light emitting elements are connected to the signal line in each of the plurality of areas.

20. The light emitting device according to claim 19, wherein the signal line is arranged between the areas.
